(19) United States
(12) Patent Application Publication
(10) Pub. No.: US 2007/0151947 A1
(43) Pub. Date: Jul. 5, 2007

(54) Method for setting plasma chamber having an adaptive plasma source, plasma etching method using the same and manufacturing method for adaptive plasma source

(76) Inventors: Yeong Su Song, Gyeonggi-do (KR); Sang Ryong Oh, Gyeonggi-do (KR); Sheung Ki Kim, Gyeonggi-do (KR); Nam Heon Kim, Gyeonggi-do (KR); Young Kun Oh, Seoul (KR); Do Hyung Lee, Gyeonggi-do (KR)

Correspondence Address: MORGAN & FINNEGAN, L.L.P., 3 WORLD FINANCIAL CENTER, NEW YORK, NY, 10281-2101, US

(21) Appl. No.: 10/583,976

(22) PCT Filed: Dec. 22, 2004
(86) PCT No.: PCT/KR04/03388

§ 371 Date: Sep. 19, 2006

(30) Foreign Application Priority Data
Dec. 22, 2003 (KR) 10-2003-0094413
Dec. 23, 2003 (KR) 10-2003-0095570
Dec. 23, 2003 (KR) 10-2003-0095523

(51) Int. Cl. C23F 1/00; H01L 21/302; C03C 15/00

(52) U.S. Cl. 216/67; 438/710

(57) ABSTRACT

Disclosed herein is a plasma chamber setting method for generating plasma in a plasma chamber. A plurality of plasma source coils, including a first plasma source coil, a second plasma source coil having an etching rate at the center part thereof higher than that of the first plasma source coil, and a third plasma source coil having an etching rate at the edge part thereof higher than that of the first plasma source coil, are prepared. The first plasma source coil is disposed on the plasma chamber, and a test wafer is etched. The etching rate for each position of the test wafer is analyzed, and first plasma source coil is replaced with the second plasma source coil or the third plasma source coil based on the analysis results.

### TECHNICAL FIELD

The present invention relates to semiconductor manufacturing equipment, and, more particularly, to a method of setting a plasma chamber having an adaptive plasma source, a plasma etching method using the same, and a method of manufacturing an adaptive plasma source.

### BACKGROUND ART

Technology for manufacturing ultra-large scale integrated (ULSI) circuit devices has been remarkably developed for the past two decades. This remarkable development was possible with the provisions of semiconductor manufacturing equipments that are capable of supporting semiconductor-manufacturing processes requiring ultimate technology. A plasma chamber, which is one type of semiconductor manufacturing equipment, has been increasingly used in a deposition process in addition to an etching process, which is a main process of the plasma chamber.

The plasma chamber is used to form plasma therein and perform processes, such as etching and deposition, with the plasma. Plasma chambers may be classified into several types based on plasma generating sources. For example, plasma chambers are classified into an electron cyclotron resonance (ECR) plasma source type plasma chamber, a helicon-wave excited plasma (HWEP) source type plasma chamber, a capacitively coupled plasma (CCP) source type plasma chamber, and an inductively coupled plasma (ICP) source type plasma chamber. Recently, an adaptive plasma source, whose structure is modified to have not only the characteristics of the inductively coupled plasma source but also the characteristics of the capacitively coupled plasma source, has been proposed.

The ICP source or the adaptive plasma source supplies radio frequency (RF) power to an induction coil so as to generate a magnetic field, and captures electrons at the center of the interior of the plasma chamber using an electric field induced by the generated magnetic field so as to generate high-density plasma even at low pressure. The ICP source or the adaptive plasma source has advantages in that the ICP source or the adaptive plasma source is simple in structure as compared to the ECR plasma source or the HWEP source, and large-sized plasma can be relatively easily obtained.

When the ICP source or the adaptive plasma source is mounted on the plasma chamber to perform an etching process, the etching rate of a wafer may be different for each position of the wafer. There are several causes that the etching rate is different, and these causes may be solved through the use of process technology as the case may be. However, difference of the etching rate due to equipment related causes, especially, the characteristics of the plasma source, is very difficult to overcome by using the process technology.

As semiconductor devices have been rapidly integrated on a large scale and design rules have been rapidly reduced, on the other hand, photoresist has been gradually thinned, and line widths of circuits have also been narrowed. For this reason, an etching process for manufacturing semiconductor devices, for example, an etching process for forming metal lines, requires very high etching selection rate.

This is mainly because, although the thickness of photoresist applied in the course of photolithography becomes thinner with large scale integration of the semiconductor devices, the thickness of an insulation layer, which is a layer to be etched, for example, the thickness of a hard mask layer becomes thicker. Furthermore, the thickness of the photoresist layer is further decreased as an organic bottom anti-reflective coating film is essentially provided under the photoresist layer. Consequently, it is important to realize high photoresist selection rate in an etching process for manufacturing large scale integrated semiconductor devices.

However, it is known that it is very difficult to realize high photoresist selection rate with the conventional ICP source type plasma chamber apparatus. This is because high plasma source power, for example, source power of approximately 800 W to 1000 W, must be applied in order to obtain a vertical profile of the metal line pattern at a desired level in the conventional ICP source type plasma chamber.

It is also known that application of such high plasma source power leads to reduction of photoresist selection rate. When plasma source power of approximately 1000 W is applied in the conventional ICP source type plasma chamber, it is difficult to realize even low photoresist selection rate of approximately 2.5 or less. Also, when such high plasma source power is applied, a wafer arcing problem is severely caused due to the high plasma source power, and a particle increasing problem is severely caused due to etching of components inside the process chamber.

In order to realize high photoresist selection rate and to solve the particle increasing problem, it is necessary to apply the plasma source power at lower level. However, the plasma source power must be maintained at high level so as to obtain a vertical profile of the metal line pattern in the conventional ICP source type plasma chamber etching apparatus, as described above. Consequently, when the plasma source power is lowered to solve the particle increasing problem and to increase the photoresist selection rate, the vertical profile of the metal line pattern is damaged. That is to say, the high photoresist selection rate is contradictory to the vertical profile of the metal line pattern in the conventional ICP source type plasma apparatus.

On that account, development of a novel plasma etching method that is capable of realizing a satisfactory vertical profile of a pattern with low plasma source power using the newly proposed adaptive plasma source, maintaining etching rate at high level so as to increase productivity, and realizing high photoresist selection rate has been required.

The adaptive plasma source comprises a coil bushing disposed in the center thereof and a plurality of unit coils helically wound on the coil bushing while one end of each of the unit coils is fixed to the coil bushing. In the plasma source with the above-described structure, the spacing between the unit coils and the sectional area of each unit coil affect density and uniformity of plasma generated in the plasma chamber. Consequently, it is required to form the plasma source with more precision. It is obvious, however, that the pursuit of excessively precise manufacture of the plasma source severely deteriorates the practicality of the plasma source.

### DISCLOSURE OF THE INVENTION

Therefore, the present invention has been made in view of the above problems, and it is an object of the present invention to provide a method of setting a plasma chamber having an adaptive plasma source to perform an etching process at uniform etching rate irrespective of positions of a wafer.

It is another object of the present invention to provide a plasma etching method that is capable of realizing a satisfactory vertical profile of a pattern with low plasma source power, maintaining etching rate at high level so as to increase productivity, and realizing high photoresist selection rate.

It is yet another object of the present invention to provide a plasma source manufacturing method that is suitable to mass production with high reliability, short processing time and reduced processing costs.

In accordance with one aspect of the present invention, the above and other objects can be accomplished by the provision of a plasma chamber setting method for disposing an adaptive plasma source coil on a plasma chamber and generating plasma in the plasma chamber using the plasma source coil, wherein the plasma chamber setting method comprising the steps of: preparing a plurality of plasma source coils including a first plasma source coil, a second plasma source coil having an etching rate at the center part thereof higher than that of the first plasma source coil, and a third plasma source coil having an etching rate at the edge part thereof higher than that of the first plasma source coil; disposing the first plasma source coil on the plasma chamber and etching a test wafer; and analyzing the etching rate for each position of the test wafer and replacing the first plasma source coil with the second plasma source coil or the third plasma source coil based on the analysis results.

Each of the plasma source coils comprises: a coil bushing disposed in the center thereof; and a plurality of unit coils helically wound on the coil bushing while one end of each of the unit coils is fixed to the coil bushing, the number of the unit coils being m, where m is a positive number of two or more, each of the unit coils having a predetermined number of turns (n) expressed by the following equation: n=a× b/m), where a and b are positive numbers, respectively.

The first plasma source coil has a coil bushing whose upper surface is flat, the second plasma source coil has a coil bushing whose upper surface is concave, and the third plasma source coil has a coil bushing whose upper surface is convex.

The spacing between the unit coils of the first plasma source coil is uniform although the radial distance from the center of the first plasma source coil is increased, the spacing between the unit coils of the second plasma source coil is gradually increased as the radial distance from the center of the second plasma source coil is increased, and the spacing between the unit coils of the third plasma source coil is gradually decreased as the radial distance from the center of the third plasma source coil is increased.

The sectional area of each of the unit coils of the first plasma source coil is uniform although the radial distance from the center of the first plasma source coil is increased, the sectional area of each of the unit coils of the second plasma source coil is gradually increased as the radial distance from the center of the second plasma source coil is increased, and the sectional area of each of the unit coils of the third plasma source coil is gradually decreased as the radial distance from the center of the third plasma source coil is increased.

The coil bushing comprises a lower bushing part and an upper bushing part, the lower bushing part being made of a material different from that of the upper bushing part.

If it is determined that the etching rate at the center part of the test wafer is higher than that at the edge part of the test wafer based on analysis results of the etching rate for each position of the test wafer, the first plasma source coil is replaced with the third plasma source coil, and then a main etching process is performed using the third plasma source coil.

If it is determined that the etching rate at the edge part of the test wafer is higher than that at the center part of the test wafer based on analysis results of the etching rate for each position of the test wafer, the first plasma source coil is replaced with the second plasma source coil, and then a main etching process is performed using the second plasma source coil.

According to the plasma chamber setting method including the adaptive plasma source, a plurality of plasma source coils having different plasma density distributions for positions are prepared, a test etching process is performed, and one of the plasma source coils is disposed based on the test results so as to perform a main etching process. Consequently, the present invention has the effect of accomplishing uniform etching rate, which is not obtained through the control of process parameters.

In accordance with another aspect of the present invention, there is provided a plasma etching method comprising the steps of: mounting a wafer in a plasma chamber of a plasma chamber apparatus, the plasma chamber apparatus comprising a plasma chamber in which a wafer is mounted, a bias power part for applying bias power to the rear surface of the wafer, a plasma source coil disposed on the plasma chamber for converting reaction gas introduced into the plasma chamber into plasma, the plasma source coil comprising a coil bushing and a plurality of unit coils helically wound on the coil bushing while one end of each of the unit coils is fixed to the coil bushing, and a source power part for applying source power to the plasma source coil to generate plasma; and supplying reaction gas into the plasma chamber while the source power is applied at a level of not more than 500 W to selectively etch the surface of the wafer.

The number of the unit coils is three or more, and the number of turns of each of the unit coils is not more than three.

The source power is applied at a level of approximately 300 W to 450 W.

The ratio of the source power to the bias power is maintained within the range of between approximately 0.2:1 and 5:1.

The reaction gas includes chlorine and boron trichloride.

According to the plasma etching method, a satisfactory pattern is realized while the source power is applied at low level, for example, at a low level of not more than 500 W. Use of the plasma source coil having the improved structure provides a vertical profile of the pattern without occurrence of undercut although the low source power is applied. Also, high photoresist selection rate, for example, photoresist selection rate of approximately 2.5 or more is realized in the course of etching. Furthermore, high etching rate of approximately 8000 Å/min, up to 10000 Å/min, is realized. In addition, high etching rate, high photoresist selection rate and vertical profile are realized at low source power. Also, damage to components inside the chamber due to plasma is effectively prevented. Consequently, the present invention has the effect of reducing costs and solving the particle increasing problem.

In accordance with yet another aspect of the present invention, there is provided a method of manufacturing a plasma source coil disposed on a plasma chamber, the plasma source coil comprising a coil bushing disposed in the center thereof and a plurality of unit coils helically wound on the coil bushing, wherein the method comprises the steps of: inserting the unit coils into grooves formed at the circumferential parts of the coil bushing, respectively, and fixing the unit coils to the coil bushing; preparing a shaping jig having depressions formed on a shaping jig body, the depressions of the shaping jig having shapes similar to those of the unit coils; preparing a precise measuring jig having depressions formed on a precise measuring jig body, the depressions of the precise measuring jig having shapes identical to those of the unit coils; inserting copper wires for the unit coils into the depressions of the shaping jig while applying heat to the copper wires for the unit coils to form helical copper wires having shapes similar to those of the unit coils; inserting the helical copper wires into the depressions of the precise measuring jig while applying heat to the helical copper wires to form unit coils; and fixing the unit coils to the coil bushing.

The widths of the depressions formed at the shaping jig are greater than the diameters of the unit coils, respectively.

The depressions of the shaping jig are grooves formed on the shaping jig body such that the depressions of the shaping jig have depths corresponding to the diameters of the unit coils, respectively.

The depressions of the precise measuring jig are grooves formed on the precise measuring jig body such that the depressions of the precise measuring jig have depths corresponding to the diameters of the unit coils, respectively.

The plasma source coil manufacturing method further comprises the step of: after the helical copper wires are inserted into the depressions of the precise measuring jig while heat is applied to the helical copper wires to form the unit coils, pressing the precise measuring jig, in which the unit coils are inserted, for a predetermined period of time.

The plasma source coil manufacturing method further comprises the step of: plating the unit coils with silver.

The unit coils are fixed to the coil bushing by means of a fixing device.

The plasma source coil manufacturing method further comprises the step of: rolling ends of the unit coils, which are not fixed to the coil bushing.

The heat treatment carried out at the steps of forming the helical copper wires and the unit coils is performed at a temperature of 250 to 350° C.

The shaping jig and the precise measuring jig are made of oxygen free copper.

According to the plasma source coil manufacturing method, the thickness of each unit coil is not changed during the manufacture of the plasma source coil, and therefore, the thickness of each unit coil is maintained at a desired level. Also, the shape of each unit coil helically wound on the coil bushing is easily formed. Consequently, the present invention has the effect of reducing the manufacturing costs and time, and thus, easily accomplishing mass production.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a flow chart schematically illustrating a plasma chamber setting method according to a preferred embodiment of the present invention;

FIG. 2 is a view showing an adaptive plasma source coil used in the plasma chamber setting method according to the preferred embodiment of the present invention;

FIG. 3 is a sectional view showing an example of a plasma chamber to which the plasma chamber setting method according to the preferred embodiment of the present invention is applied;

FIG. 4 is a sectional view showing another example of the plasma chamber to which the plasma chamber setting method according to the preferred embodiment of the present invention is applied;

FIG. 5 is a sectional view showing another example of the plasma chamber to which the plasma chamber setting method according to the preferred embodiment of the present invention is applied;

FIG. 6 is a sectional view showing still another example of the plasma chamber to which the plasma chamber setting method according to the preferred embodiment of the present invention is applied;

FIG. 7 is a view showing another example of the plasma source coil used in the plasma chamber setting method according to the preferred embodiment of the present invention;

FIG. 8 is a graph illustrating relations between the radial distance from the center and the coil spacing of the plasma source coil shown in FIG. 7;

FIG. 9 is a view showing still another example of the plasma source coil used in the plasma chamber setting method according to the preferred embodiment of the present invention;

FIG. 10 is a graph illustrating relations between the radial distance from the center and the sectional area of the plasma source coil shown in FIG. 9;

FIG. 11 is a graph illustrating relations between the radial distance from the center and the coil spacing of the plasma source coil shown in FIG. 9;

FIGS. 12 and 13 are sectional views illustrating the plasma chamber setting method according to the preferred embodiment of the present invention, respectively;

FIG. 14 is a flow chart schematically illustrating a plasma etching method according to another preferred embodiment of the present invention;

FIGS. 15 and 16 are sectional views schematically illustrating the plasma etching method according to the preferred embodiment of the present invention, respectively;

FIG. 17 is a scanning electron micrograph (SEM) illustrating the effect of the plasma etching method according to the preferred embodiment of the present invention;

FIG. 18 is a flow chart schematically illustrating a plasma source coil manufacturing method according to still another preferred embodiment of the present invention;

FIGS. 19 to 21 are views respectively showing a jig used in the plasma source coil manufacturing method according to the preferred embodiment of the present invention;

FIG. 22 is a view illustrating attachment of unit coils to a coil bushing in the plasma source coil manufacturing method according to the preferred embodiment of the present invention; and

FIG. 23 is a view showing a plasma source manufactured by the plasma source coil manufacturing method according to the preferred embodiment of the present invention.

### BEST MODE FOR CARRYING OUT THE INVENTION

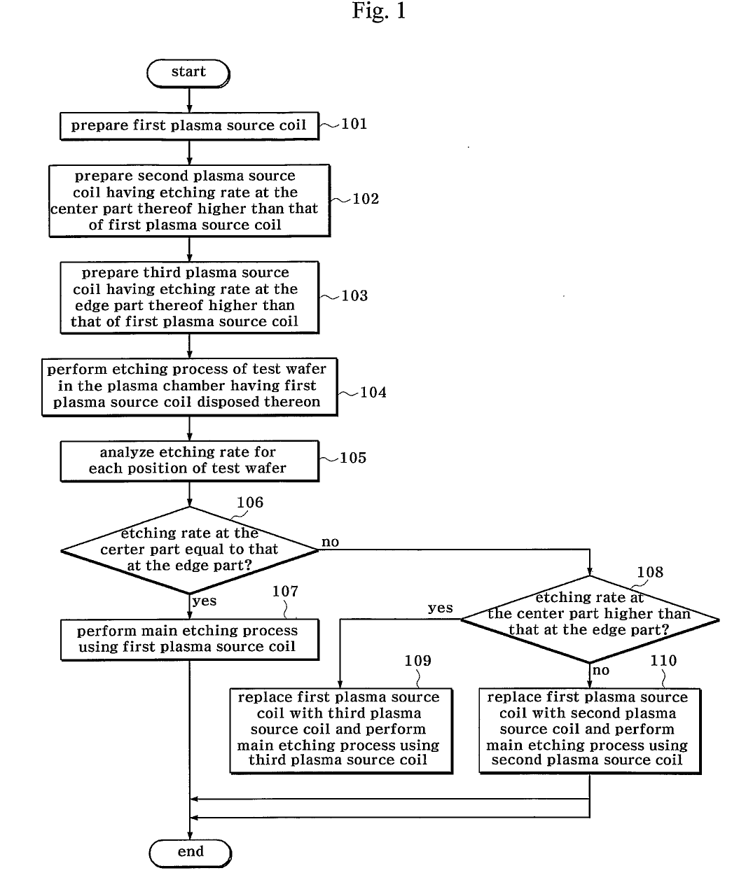

FIG. 1 is a flow chart schematically illustrating a plasma chamber setting method according to a preferred embodiment of the present invention.

As shown in FIG. 1, a first plasma source coil is prepared first (Step 101). Subsequently, a second plasma source coil, which has an etching rate at the center part thereof higher than that of the first plasma source coil, is prepared (Step 102). Also, a third plasma source coil, which has an etching rate at the edge part thereof higher than that of the first plasma source coil, is prepared (Step 103). The first, second and third plasma source coils have the same plan shape while the first, second and third plasma source coils have different sectional shapes.

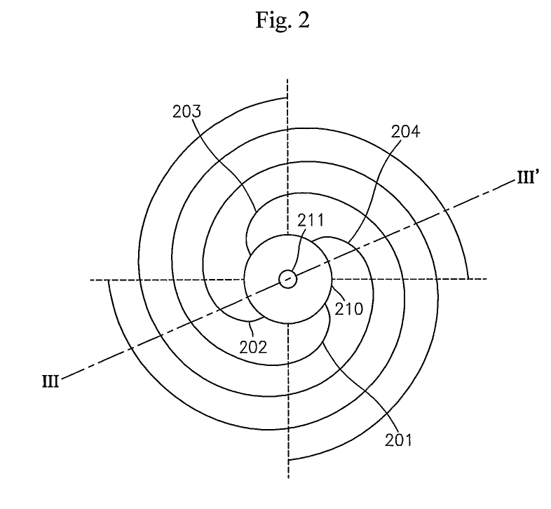

Referring to FIG. 2, each of the first, second and third plasma source coils comprises: a coil bushing 210 disposed in the center thereof; and a plurality of unit coils 201, 202, 203 and 204 helically wound on the coil bushing 210. In this embodiment, the number of the unit coils is four. However, the number of the unit coils is not necessarily restricted to four. For example, the number (m) of the unit coils may be a positive number greater than or equal to two. Each of the unit coils 201, 202, 203 and 204 has a predetermined number of turns (n). The number of turns (n) may be a positive number. For example, the number of turns (n) is expressed by the following equation: n=a× (b/m), where a and b are positive numbers, respectively. The coil bushing 210 is made of the same material as the plurality of unit coils 201, 202, 203 and 204. For example, the coil bushing 210 is made of a copper material in the case that the each of the unit coils 201, 202, 203 and 204 is made of a copper material. Although, the coil bushing 210 may be made of a material different from that of each of the unit coils 201, 202, 203 and 204 as the case may be. In this case, however, it should be noted that the coil bushing 210 may be made of a conductive material. At the center of the coil bushing 210 is disposed a supporting rod 211, which extends vertically from the upper surface of the coil bushing 210. The supporting rod 211 is also made of a conductive material, such as copper.

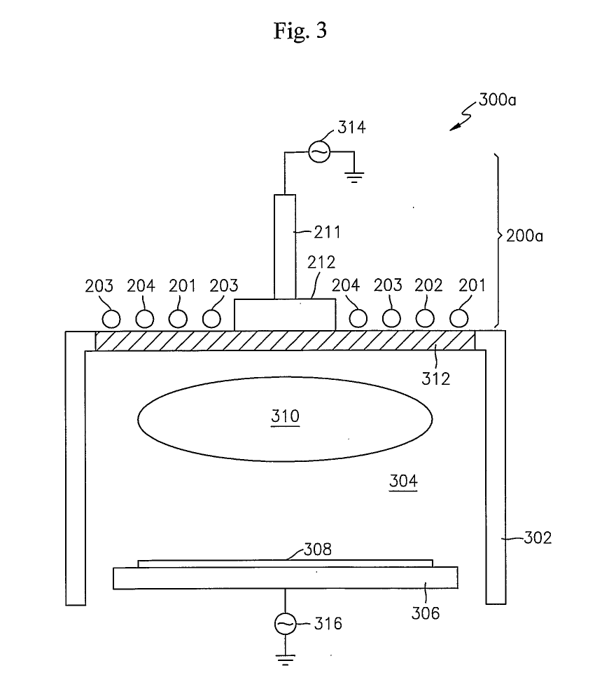

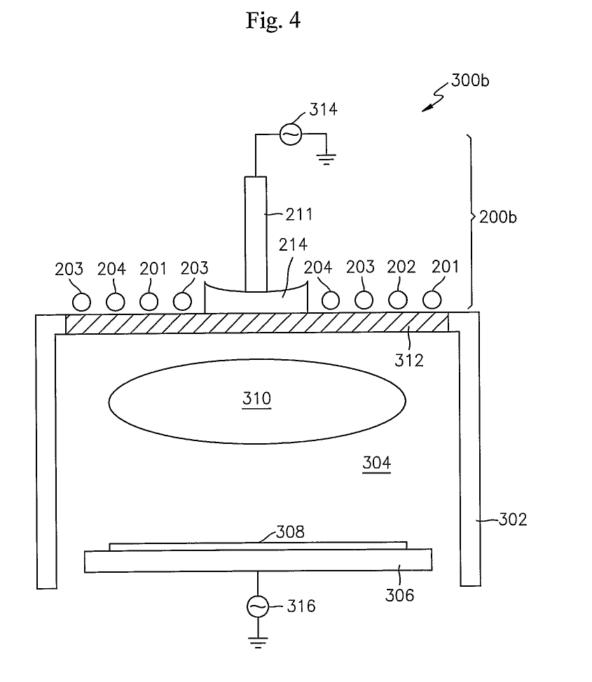

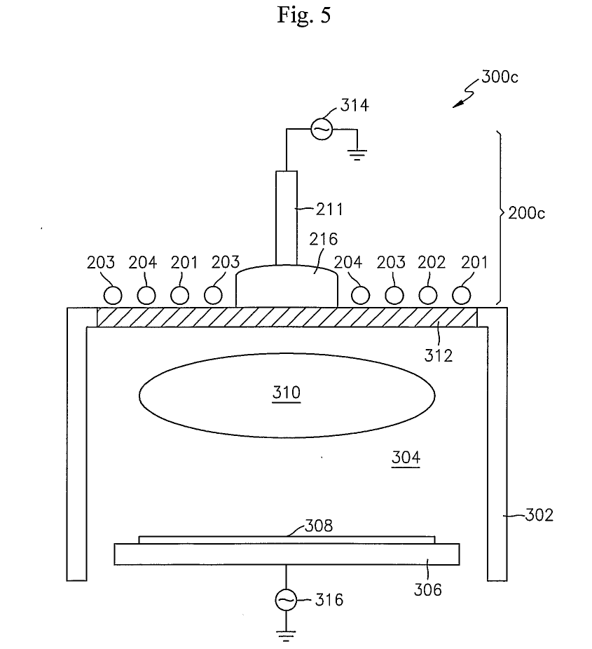

As shown in FIGS. 3 to 5, the first plasma source coil 200a has a coil bushing 212 whose upper surface is flat, the second plasma source coil 200b has a coil bushing 214 whose upper surface is concave, and the third plasma source coil 200c has a coil bushing 216 whose upper surface is convex. The coil bushing 214 of the second plasma source coil 200b has a thickness less than that of the coil bushing 212 of the first plasma source coil 200a. As a result, the plasma density is higher at the center part of the second plasma source coil 200b than at the edge part of the second plasma source coil 200a, and therefore, the etching rate is higher at the center part of the second plasma source coil 200b than at the edge part of the second plasma source coil 200a. On the other hand, the coil bushing 216 of the third plasma source coil 200c has a thickness greater than that of the coil bushing 212 of the first plasma source coil 200a. As a result, the plasma density is higher at the edge part of the third plasma source coil 200c than at the center part of the third plasma source coil 200c, and therefore, the etching rate is higher at the edge part of the third plasma source coil 200c than at the center part of the third plasma source coil 200c. The above-mentioned characteristics may be reversed in some cases, for example, in the case that the etching rate is influenced not by the plasma density but by the presence of neutrons in the plasma chamber and the results of their chemical reactions. In this case, the second plasma source coil 200b is substituted for the third plasma source coil 200c, and vice versa.

As shown in FIG. 3, a plasma chamber 300a, on which the first plasma source coil 200a is disposed, has an inner space 304 having a predetermined size, which is defined by an outer chamber wall 302 and a dome 312. Although the inner space 304 is shown open to the outside in the drawing for the purpose of clarity, the inner space 304 is actually isolated from the outside so that a vacuum state is maintained in the inner space 304. In the inner space 304 is disposed a wafer supporting table 306, which is placed at the lower part of the inner space 304 for supporting a wafer 308 to be processed. To the wafer supporting table 306 is connected an RF power supply 316, which is a bias power part. The first plasma source coil 200a is disposed at the outer surface of the dome 312 for generating plasma 310 in the inner space 304. The first plasma source coil 200a has a plan shape as shown in FIG. 2. To the supporting rod 211 of the first plasma source coil 200a is connected an RF power supply 314, which is a source power part. Although not shown in the drawing, the ends of the unit coils 201, 202, 203 and 204 are connected to grounding terminals, respectively. The above-described structure of the plasma chamber 300a having the first plasma source coil 200a disposed thereon is identically applied to those of a plasma chamber 300b having the second plasma source coil 200b disposed thereon and a plasma chamber 300c having the third plasma source coil 200c disposed thereon.

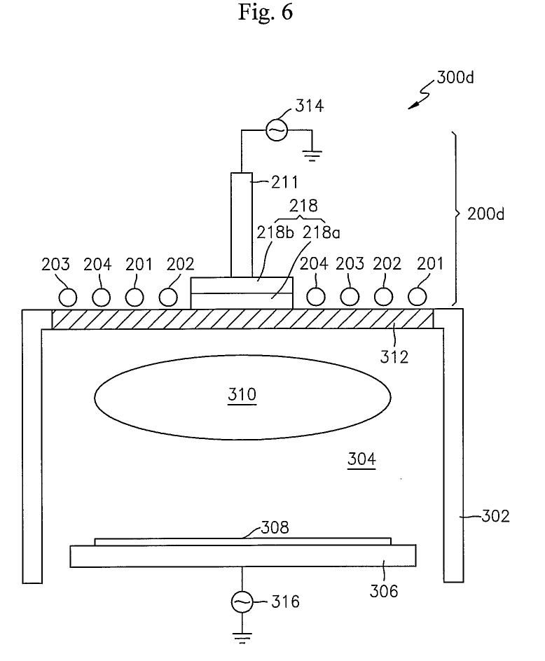

FIG. 6 is a sectional view showing still another example of the plasma chamber to which the plasma chamber setting method according to the present invention is applied. Components of the plasma chamber shown in FIG. 6, which are identical to those of the plasma chamber shown in FIG. 3, are indicated by the same reference numerals as those of the plasma chamber shown in FIG. 3.

Referring to FIG. 6, a plasma source coil 200d is different from the first to third plasma source coil described above with reference to FIGS. 3 to 5 in that the plasma source coil 200d has a double-layered coil bushing 218, which comprises a lower bushing part 218a and an upper bushing part 218b. The lower bushing part 218a of the double-layered coil bushing 218 may be made of a material different from that of the upper bushing part 218b of the double-layered coil bushing 218 so that the plasma density is higher at the center part thereof than at the edge part thereof, and vice versa.

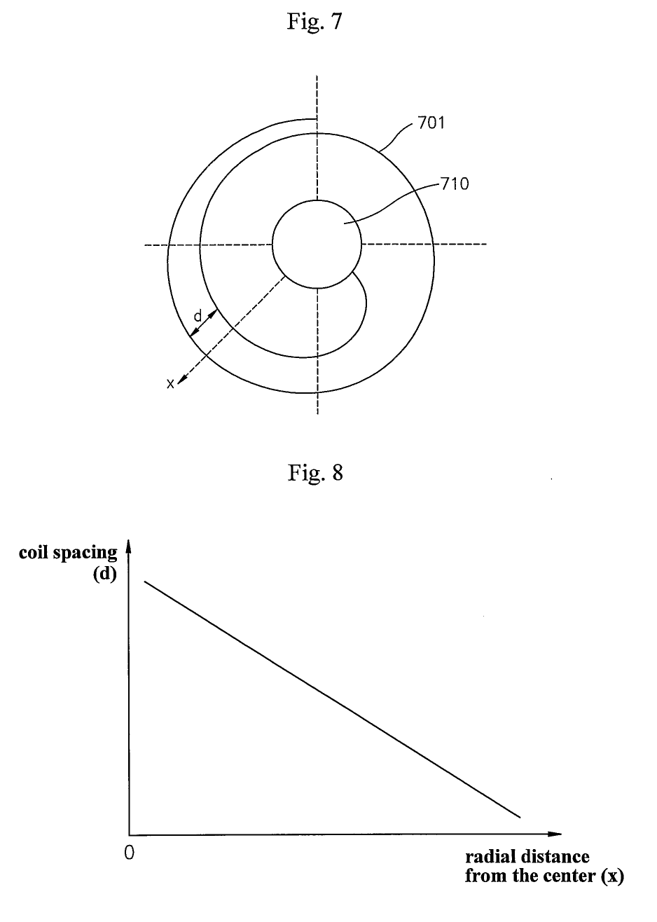

FIG. 7 is a view showing another example of the plasma source used in the plasma chamber setting method according to the present invention, and FIG. 8 is a graph illustrating relations between the radial distance from the center and the coil spacing of the plasma source coil shown in FIG. 7.

As shown in FIGS. 7 and 8, a single unit coil 701 is helically wound on a coil bushing 710 disposed at the center of the plasma source coil while one end of the unit coil 701 is fixed to the coil bushing 710. Especially, the unit coil 701 is characterized in that the coil spacing (d) is gradually decreased as the radial distance from the center thereof in the x direction is increased. In other words, the coil spacing (d) is gradually increased toward the center thereof while the coil spacing (d) is gradually decreased toward the edge thereof. As a result, the spacing between current flowing through the unit coil 701 is decreased as the unit coil 701 is far away from the center thereof in the radial direction, and therefore, the total amount of current passing through the unit area is increased. Consequently, the current density is increased as the coil is far away from the center thereof in the radial direction, and therefore, the plasma density at a position corresponding to the edge of the wafer is increased. Such a plasma source coil 710 may be used as the third plasma source coil. Although not shown in the drawings, the second plasma source coil has the reversed structure. Specifically, the unit coil 701 is characterized in that the coil spacing (d) is gradually increased as the radial distance from the center thereof in the x direction is increased. The same principle is identically applied to a plurality of unit coils, although the single unit coil has been described above as an example.

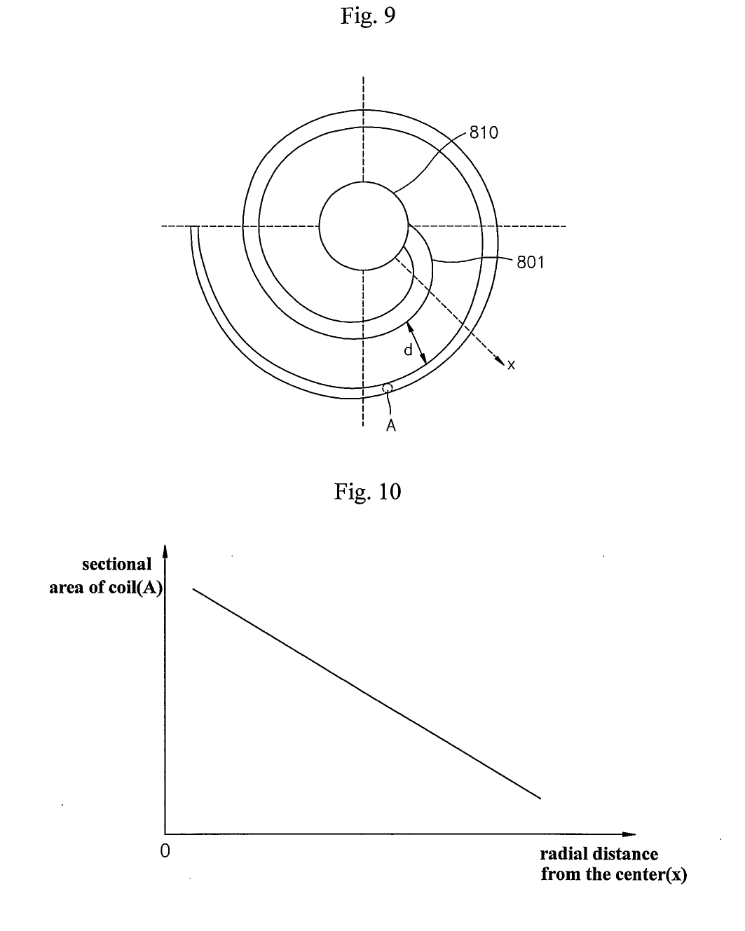

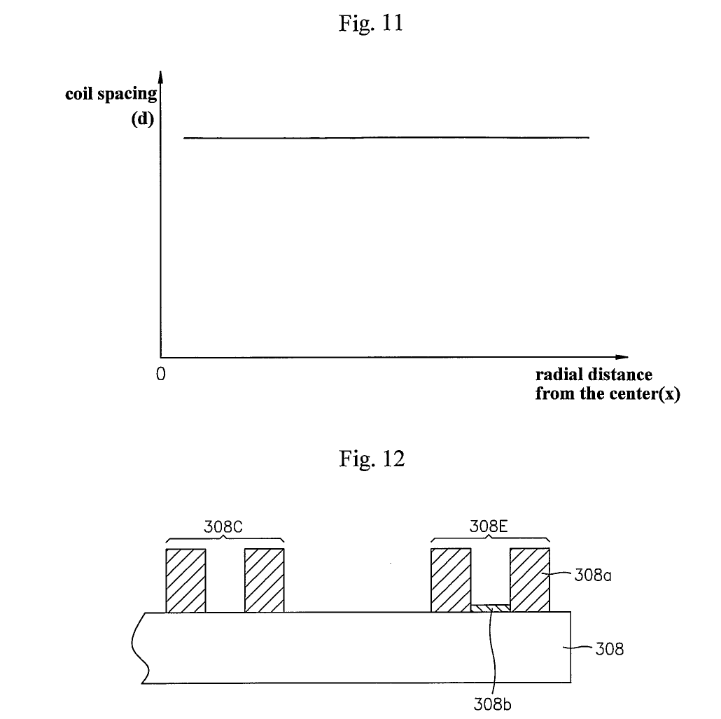

FIG. 9 is a view showing still another example of the plasma source coil used in the plasma chamber setting method according to the present invention, FIG. 10 is a graph illustrating relations between the radial distance from the center and the sectional area of the plasma source coil shown in FIG. 9, and FIG. 11 is a graph illustrating relations between the radial distance from the center and the coil spacing of the plasma source coil shown in FIG. 9.

Referring to FIGS. 9, 10 and 11, a single unit coil 801 is helically wound on a coil bushing 810 disposed at the center of the plasma source coil while one end of the unit coil 801 is fixed to the coil bushing 810. Especially, the unit coil 801 is characterized in that the sectional area (A) of the coil is gradually decreased as the radial distance from the center thereof in the x direction is increased while the coil spacing (d) is uniformly maintained although the radial distance from the center thereof in the x direction is increased. In other words, the sectional area (A) of the coil is gradually increased toward the center thereof while the sectional area (A) of the coil is gradually decreased toward the edge thereof. As a result, the density of current flowing through the unit coil 801 is increased as the coil is far away from the center thereof in the radial direction although the amount of current is the same, and therefore, the plasma density at a position corresponding to the edge of the wafer is increased. Such a plasma source coil 810 may be used as the third plasma source coil. Although not shown in the drawings, the second plasma source coil has the opposite structure. Specifically, the unit coil 801 is characterized in that the sectional area (A) of the coil is gradually increased as the radial distance from the center thereof in the x direction is increased. The same principle is identically applied to a plurality of unit coils, although the single unit coil has been described above as an example.

In the above, the steps (Step 101, Step 102 and Step 103) of preparing the first, second and third plasma source coils have been described based on the structures of the first to third plasma source coils. It should be noted, however, that the first to third plasma source coils may be manufactured using other structures different from those of the plasma source coils described above. In any case, the second plasma source coil has the etching rate at the center part thereof higher than at the edge part thereof as compared to the first plasma source coil, and the third plasma source coil has the etching rate at the edge part thereof higher than at the center part thereof as compared to the first plasma source coil.

Referring back to FIG. 1, a step of etching a test wafer is performed in the plasma chamber having the first plasma source coil disposed thereon (Step 104). After the etching step is complete, the etching rate for each position of the test wafer is analyzed (Step 105). Based on the analysis results, it is determined whether the etching rate at the center part thereof is equal to that at the edge part thereof (Step 106). The term “equal” means that the etching rate is within an allowable error range. If it is determined that the etching rate at the center part thereof is equal to that at the edge part thereof, a main etching process is performed using the first plasma source coil (Step 107). If it is determined that the etching rate at the center part thereof is not equal to that at the edge part thereof, on the other hand, it is determined whether the etching rate is higher at one part or another, for example, whether the etching rate at the center part thereof is higher than that at the edge part thereof (Step 108). If it is determined that the etching rate at the center part thereof is higher than that at the edge part thereof, the first plasma source coil is replaced with the third plasma source coil, and then a main etching process is performed using the third plasma source coil (Step 109). When the third plasma source coil is used, the etching rate at the edge part thereof is more increased, and therefore, entirely uniform etching results are obtained. If it is determined that the etching rate at the edge part thereof is higher than that at the center part thereof, the first plasma source coil is replaced with the second plasma source coil, and then a main etching process is performed using the second plasma source coil (Step 110). When the second plasma source coil is used, the etching rate at the center part thereof is more increased, and therefore, entirely uniform etching results are obtained.

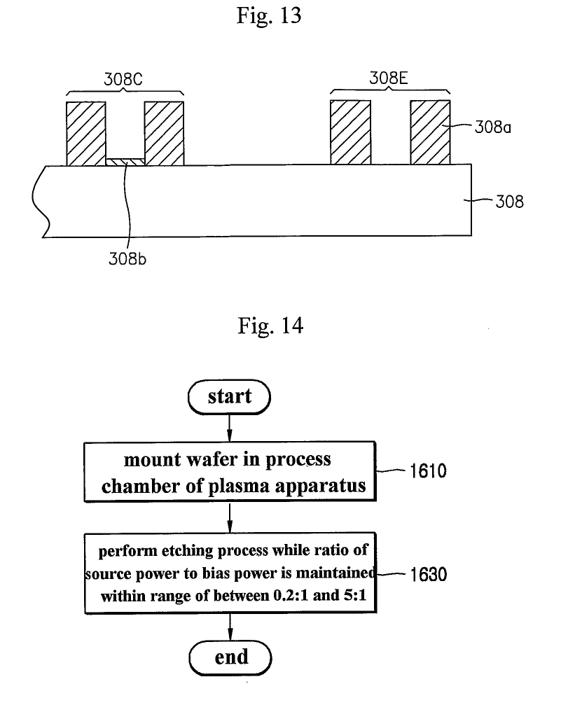

FIGS. 12 and 13 are sectional views illustrating the etching results based on the determination at Step 108.

Referring to FIGS. 12 and 13, a predetermined pattern may be formed at the wafer 308, which is loaded and etched in the plasma chamber. For example, a poly-silicon film pattern 308a may be formed on the surface of the wafer 308. Between the surface of the wafer and the poly-silicon film pattern 308a may be interposed an insulation film (not shown) so that the poly-silicon film pattern 308a can be used as a gate conduction film. Alternatively, the poly-silicon film pattern 308a may be directly formed on the surface of the wafer or formed on another film so that the poly-silicon film pattern 308a can be used for other purposes. The poly-silicon film pattern 308a is disposed not only on the center part 308C of the wafer 308 but also on the edge part 308E of the wafer 308. In order to form such a poly-silicon film pattern 308a, a poly-silicon film is formed on the surface of the wafer 308, and then a mask film pattern (not shown) is formed on the poly-silicon film. Subsequently, an etching process is performed using the mask film pattern as an etching mask to remove the poly-silicon film exposed by the mask film pattern. As a result, the poly-silicon film pattern 308a shown in the drawings is obtained.

Step 108 of the plasma chamber setting method according to the present invention, i.e., the step of determining whether the etching rate at the center part is higher than that at the edge part, is carried out by analyzing the etched test wafer. When the etching rate at the center part of the wafer is higher than that at the edge part of the wafer, the center part 308C of the wafer 308 is completely etched while the edge part 308E of the wafer 308 is incompletely etched, as shown in FIG. 12. When the etching rate at the center part of the wafer is lower than that at the edge part of the wafer, on the other hand, the center part 308C of the wafer 308 is incompletely etched while the edge part 308E of the wafer 308 is completely etched, as shown in FIG. 13. Consequently, Step 109 is performed in the case of FIG. 12, and Step 110 is performed in the case of FIG. 13.

In the above description, three plasma source coils are used, although more than three plasma source coils, for example, a plurality of plasma source coils having different etching rates for positions of the wafer, may also be used.

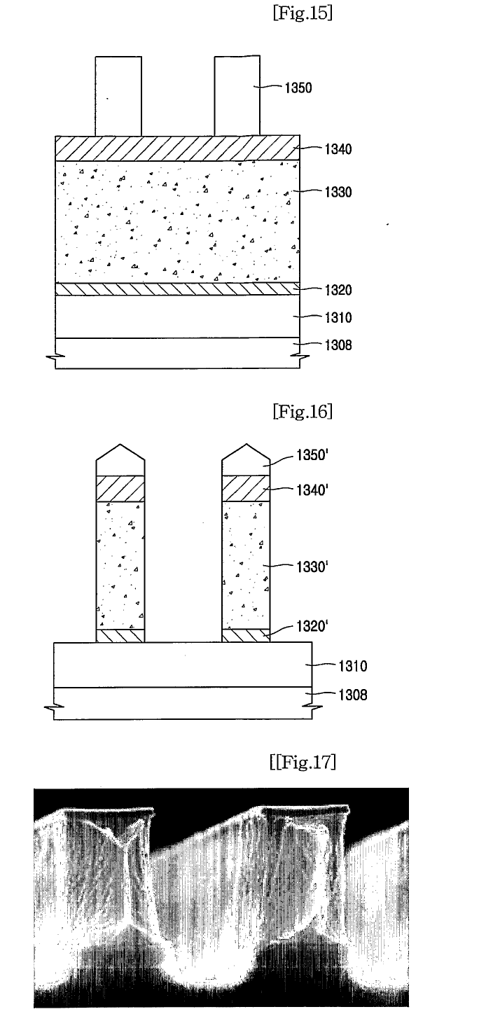

FIG. 14 is a flow chart schematically illustrating a plasma etching method according to the present invention, and FIGS. 15 and 16 are sectional views schematically illustrating the plasma etching method according to the present invention, respectively.

Referring to FIG. 14, the plasma etching method according to the present invention begins with mounting the wafer 308 (see FIG. 3) in the plasma chamber 300a (see FIG. 3), which has already been described with reference to FIG. 3 (Step 1610).

At this time, the wafer 308 is a wafer having a barrier layer 1320, a metal layer 1330 and an anti-reflection layer 1340 formed in turn on a lower material layer 1310, such as a silicon oxide layer, as shown in FIG. 15. On the anti-reflection layer 1340 is formed a photoresist later pattern 1350 so that the metal layer 1330 is patterned with a metal line pattern.

After the wafer 308 is disposed on the wafer supporting table 306 in the plasma chamber 300a, reaction gas, for example, reaction gas including chlorine (C1₂) and boron trichloride (BC1₃) as an etchant for etching the metal layer, is supplied into the process chamber 300a (see FIG. 3). Preferably, the ratio of chlorine to boron trichloride is 2:1 or more. RF power from the RF power supply 314 (see FIG. 3), which is a source power part, is applied to the plasma source coil 200a (see FIG. 3) so as to generate plasma. Bias power from the RF power supply 316 (see FIG. 3), which is a bias power part, is applied to the rear surface of the wafer 308 (see FIG. 3) so as to perform an etching process (Step 1630).

At this time, the source power supplied from the RF power supply 314, which is the source power part, is not more than approximately 500 W. Also, the minimum RF source power is approximately 10 W to 100 W, which is necessary for the reaction gas to be excited into plasma. Preferably, the source power is approximately 300 W to 450 W. On the other hand, the RF bias power is approximately 100 W to 200 W. At this time, the ratio of the source power to the bias power is preferably maintained within the range of between approximately 0.2:1 and 5:1. The reason why low source power, i.e., source power of not more than 500 W, is applied is that higher photoresist selection rate can be obtained.

The conventional IPC source type plasma apparatus provides high RF source power of approximately 800 W to 1000 W. In this case, high photoresist selection rate is not accomplished although reduction of the etching amount is prevented, and therefore, upper edge of the metal layer to be patterned or the anti-reflection layer is lost. In order to solve the above problem, the adaptive plasma chamber according to the present invention provides RF source power of not more than approximately 500 W to generate plasma.

Through the above-described etching process, a barrier layer pattern 1320′, a metal layer pattern 1330′ and an anti-reflection layer pattern 1340′ are obtained as shown in FIG. 16. At this time, a residual photoresist pattern 1350′ sufficiently covers the anti-reflection layer pattern 1340′. This is because high photoresist selection rate is accomplished based on the etching method according to the present invention. Furthermore, high etching rate is may be accomplished simultaneously with the accomplishment of the high photoresist selection rate, and the formed pattern may have a vertical profile.

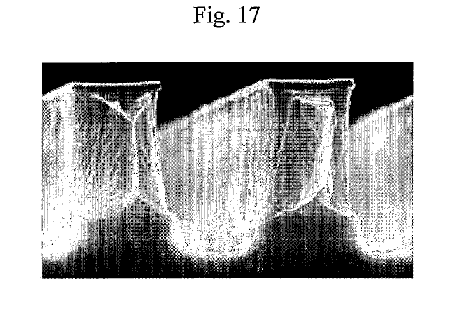

The above described effect of the present invention is proven by the scanning electron micrograph (SEM) shown in FIG. 17.

FIG. 17 is a scanning electron micrograph (SEM) illustrating the effect of the plasma etching method according to the present invention.

Referring to FIG. 17, it can be seen that the pattern formed using the plasma etching method according to the present invention has a vertical profile without loss of the top shoulder. The micrograph of FIG. 17 was obtained from the pattern structure formed at the material later structure on the wafer 308, which has been described above with reference to FIGS. 15 and 16, using the etching method according to the present invention.

More specifically, the lower material layer 1310, such as a silicon oxide layer, is formed on the wafer 308 first, as shown in FIG. 15. The barrier layer 1320 having a thickness of approximately 300 Å to 1500 Å, such as a titanium/titanium nitride layer (Ti/TiN layer), is formed on the lower material layer 1310. The metal layer 1330 having a thickness of approximately 8000 Å, such as an aluminum (Al) layer, is formed on the barrier layer 1320. The anti-reflection layer 1340 having a thickness of approximately 500 Å to 1000 Å, such as a titanium nitride layer, is formed on the metal layer 1330. Finally, the photoresist layer pattern 1350 is formed on the anti-reflection layer 1340.

Subsequently, the selective etching process is performed while low source power is applied as described above with reference to FIG. 14 to pattern the wafer as shown in FIG. 16. More specifically, the adaptive plasma source coil as shown in FIG. 2 is disposed on the plasma chamber as shown in FIG. 3. At this time, the number of unit coils is three, and the wound number of each unit coil is two.

Although two or more unit coils may be used, and the wound number of each unit may be any positive number, the above-described construction is adopted to prove the effect of the plasma etching method according to the present invention.

After the wafer 308 is placed on the wafer supporting table 306 in the plasma chamber with the above-stated construction, reaction gas including chlorine and boron trichloride in the ratio of approximately 2:1 is supplied into the plasma chamber, and then etching process is performed while the source power of approximately 450 W and the bias power of approximately 300 W are applied. Thereafter, the residual photoresist layer pattern is removed by means of ashing and stripping. The micrograph of the vertical section of the resulting structure, which is shown in FIG. 17, was taken by the scanning electron microscope.

It can be seen from the micrograph of FIG. 17 that the metal layer pattern 1330′, i.e., the aluminum layer pattern, has a vertical profile. This proves the fact that occurrence of undercut is prevented although the low source power, for example, the source power of approximately 450 W, is applied. At this time, the actual etching amount was very large. For example, the etching amount was approximately 8000 Å/min to 10000 Å/min. This proves the fact that the plasma etching method according to the present invention accomplishes very high process efficiency.

Also, it is proved that the upper shoulder of the aluminum layer pattern, substantially the titanium nitride layer pattern, which is the anti-reflection layer pattern 1340′, is not lost. No loss of the upper shoulder proves that the photoresist layer pattern 1350′ is maintained until the etching process is completed. In other words, it is proved that a very high photoresist selection rate can be accomplished. Practically, a photoresist selection rate of approximately three or more can be accomplished.

The above-mentioned effect is very difficult to accomplish using the conventional IPC source type plasma chamber. In the conventional IPC source type plasma chamber, source power of approximately 1000 W or more must be applied to obtain the same wafer structure as that seen in the micrograph of FIG. 17 in order to accomplish an etching rate of approximately 8000 Å/min and to accomplish a vertical profile. In this case, it is difficult to accomplish the photoresist selection rate of approximately 2 or more, and therefore, the upper shoulder is lost. Such loss of the upper shoulder affects line width and resistance of the aluminum layer pattern. Consequently, it is difficult to apply the conventional IPC source type plasma chamber to mass production.

In the case that the source power is lowered to increase the photoresist selection rate so that the loss of the upper shoulder is prevented in the conventional IPC source type plasma chamber, it is very difficult to obtain the vertical profile of the pattern. When low source power of approximately 500 W was actually applied in the conventional IPC source type plasma chamber, it was observed that the undercut was excessively formed at the pattern.

When low source power of approximately 500 W is applied to generate plasma according to the present invention, on the other hand, wafer arcing and damage to inner components of the plasma chamber due to plasma, which inevitably occur when high source power is applied, are effectively prevented. Consequently, a particle problem, which excessively occurs due to the damage, is remedied, and therefore, costs necessary to perform the etching process are reduced.

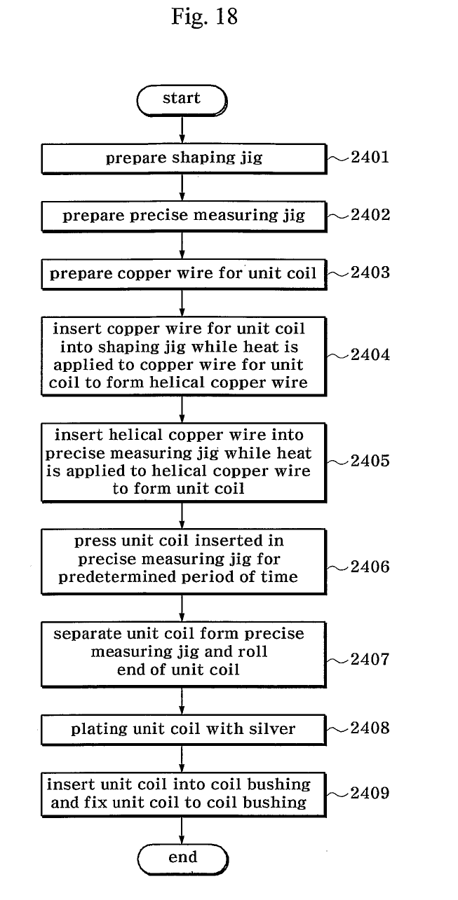

FIG. 18 is a flow chart schematically illustrating a plasma source coil manufacturing method according to the present invention, and FIG. 23 is a view showing a plasma source coil manufactured by the plasma source coil manufacturing method according to the present invention.

Referring first to FIG. 23, the plasma source coil 2900 manufactured by the plasma source coil manufacturing method according to the present invention comprises: a coil bushing 2910 disposed in the center thereof; and a plurality of unit coils 2921, 2922 and 2923 helically wound on the coil bushing 2910 while one end of each unit coil is fixed to the coil bushing 2910.

Referring now to FIG. 18, a shaping jig and a precise measuring jig are prepared first so as to manufacture the plasma source coil 2900 with the above-stated construction (Step 2401 and Step 2402). The shaping jig and the precise measuring jig have the same shape. Accordingly, the shaping jig will be described below in detail, and then the difference between the shaping jig and the precise measuring jig will be described in succession.

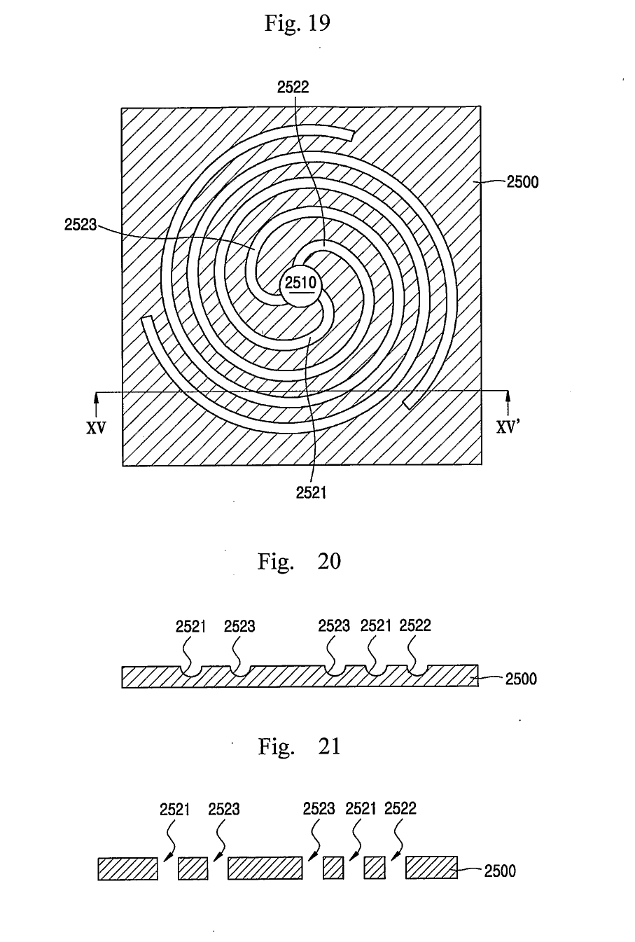

FIGS. 19 to 21 schematically show the above-mentioned shaping jig, respectively. FIGS. 20 and 21 are sectional views taken along line XV-XV′ of FIG. 19, showing examples of the shaping jig.

As shown in FIGS. 19 to 21, the shaping jig comprises: a shaping jig body 2500; and a plurality of depressions 2510, 2521, 2522 and 2523 formed on the shaping jig body 2500. Especially, each of the depressions 2510, 2521, 2522 and 2523 are formed in a shape similar to that of the plasma source coil 2900 (see FIG. 23), by which the shaping jig is distinguished from the precise measuring jig. Specifically, the shaping jig has the depressions 2510, 2521, 2522 and 2523 formed in shapes similar to those of the unit coils of the plasma source coil 2900 while the precise measuring jig has the depressions 2510, 2521, 2522 and 2523 formed in the same shapes as those of the unit coils of the plasma source coil 2900. Consequently, the widths of the depressions 2521, 2522 and 2523 of the shaping jig are greater than the diameters of the unit coils 2921, 2922 and 2923 of the plasma source coil 2900, respectively. On the other hand, the widths of the depressions 2521, 2522 and 2523 of the precise measuring jig are equal to the diameters of the unit coils 2921, 2922 and 2923 of the plasma source coil 2900, respectively. Except for the above-mentioned difference, the shaping jig and the precise measuring jig are substantially the same.

The depression 2510 corresponds to the coil bushing 2910, and the depressions 2521, 2522 and 2523 correspond to the unit coils 2921, 2922 and 2923, respectively. As shown in FIG. 20, the depressions 2521, 2522 and 2523 may be grooves formed on the shaping jig body 2500 such that the depressions 2521, 2522 and 2523 have depths corresponding to the diameters of the unit coils 2921, 2922 and 2923, respectively.

Referring back to FIG. 18, a copper wire for the unit coil is prepared (Step 2403). The copper wire for the unit coil is made of oxygen free copper having an almost 100% degree of purity, although the copper wire for the unit coil may be made of another material in some cases. The copper wire for the unit coil is a lengthy straight copper wire. The copper wire for the unit coil is inserted into the depression 2521, 2522 or 2523. The copper wire for the unit coil is formed in a straight shape while the depression 2521, 2522 or 2523 is formed in a helical shape, and therefore, the copper wire for the unit coil may not be easily inserted into the depression 2521, 2522 or 2523. In this case, an additional device, for example, an auxiliary helical jig may be used. The copper wire for the unit coil is inserted into the depression 2521, 2522 or 2523 while heat is applied to the copper wire for the unit coil to form a helical copper wire (Step 2404). The heat applying process may be performed at a temperature of approximately 250 to 350° C. The reason why the heat is applied to the copper wire for the unit coil is that the copper wire for the unit coil bent in the helical shape is easily arranged in the helical shape. Also, the size of the depression 2521, 2522 or 2523 of the shaping jig is larger than that of the copper wire for the unit coil. Consequently, Step 2404 is performed without difficulty. The helical copper wire obtained by performing Step 2404 has a helical shape not identical but similar to that of the unit coil 2921, 2922 or 2923.

Subsequently, the helical copper wire is inserted into the precise measuring jig while heat is applied to the helical copper wire to form the unit coil 2921, 2922 or 2923 (Step 2405). Since the helical copper wire has a helical shape similar to that of the unit coil 2921, 2922 or 2923, the helical copper wire is easily inserted into the depression of the precise measuring jig. When the helical copper wire is heated to a temperature of approximately 250 to 350° C. in this state, the unit coil 2921, 2922 or 2923 is completed. Thereafter, the precise measuring jig is pressed by an additional pressing device, such as a surface plate, until the unit coil 2921, 2922 or 2923 is cooled in order to prevent thermal deformation of the unit coil 2921, 2922 or 2923 (Step 2406). Subsequently, the unit coil 2921, 2922 or 2923 is separated from the precise measuring jig, and then the end of the unit coil 2921, 2922 or 2923 is rolled (Step 2407). After that, the unit coil 2921, 2922 or 2923 is plated with silver (Step 2408). The silver plating is carried out using an electric plating method. The thickness of the silver plating part is decided in consideration of skin depth.

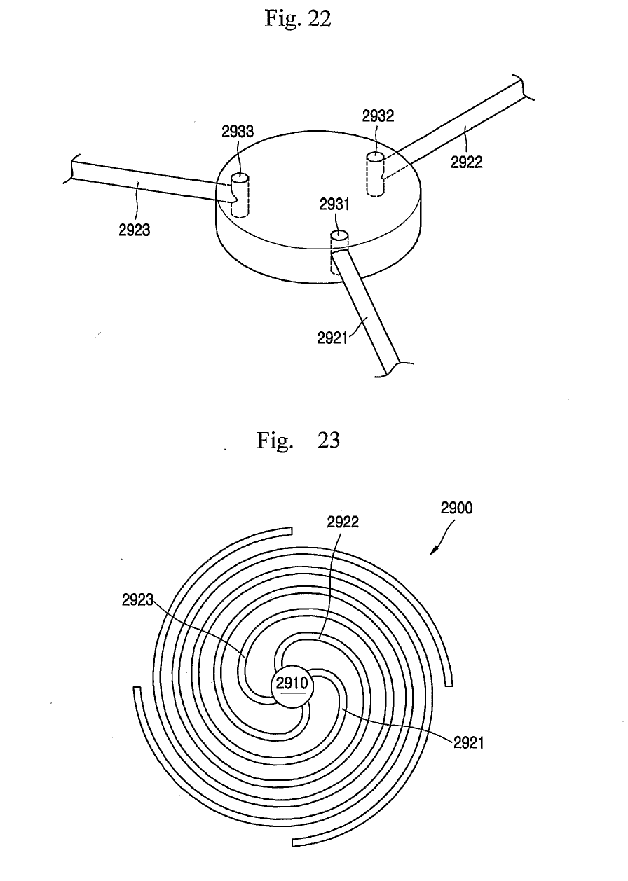

Finally, the unit coil 2921, 2922 or 2923 is fixed to the coil bushing 2910 by means of a fixing device (Step 2409). Specifically, one end of the unit coil 2921, 2922 or 2923 is inserted into one of grooves formed at the circumferential part of the coil bushing 2910, as shown in FIG. 22, and then the unit coil 2921, 2922 or 2923 is fixed to the coil bushing 2910 by means of an additional fixing device 2931, 2932 or 2933. The end of the unit coil 2921, 2922 or 2923, which is inserted in the groove of the coil bushing 2910, is not rolled. According to circumstances, the rolling process may be performed after the unit coil 2921, 2922 or 2923 is inserted into and fixed to the coil bushing 2910. Alternatively, the step of fixing the unit coil 2921, 2922 or 2923 to the coil bushing 2910 by means of the fixing device may be carried out first. In this case, it is ensured that the shaping jig and the precise measuring jig are provided with grooves, into which the coil bushing 2910 will be inserted.

In the above description, the number of the unit coils 2921, 2922 and 2923 is three for example, although four or more unit coils may be used without limits.

### Industrial Applicability

The present invention is applied to the semiconductor manufacturing equipment field adopting an adaptive plasma source and the semiconductor manufacturing field using the same.

1. A plasma chamber setting method for disposing an adaptive plasma source coil on a plasma chamber and generating plasma in the plasma chamber using the plasma source coil, wherein the plasma chamber setting method comprises the steps of:
preparing a plurality of plasma source coils including a first plasma source coil, a second plasma source coil having an etching rate at the center part thereof higher than that of the first plasma source coil, and a third plasma source coil having an etching rate at the edge part thereof higher than that of the first plasma source coil;
disposing the first plasma source coil on the plasma chamber and etching a test wafer; and
analyzing the etching rate for each position of the test wafer and replacing first plasma source coil with the second plasma source coil or the third plasma source coil based on the analysis results.

2. The method as set forth in claim 1, wherein each of the plasma source coils comprises: a coil bushing disposed in the center thereof; and a plurality of unit coils helically wound on the coil bushing while one end of each of the unit coils is fixed to the coil bushing, the number of the unit coils being m, where m is a positive number of two or more, each of the unit coils having a predetermined number of turns (n) expressed by the following equation: n=a× (b/m), where a and b are positive numbers, respectively.

3. The method as set forth in claim 2, wherein the first plasma source coil has a coil bushing whose upper surface is flat, the second plasma source coil has a coil bushing whose upper surface is concave, and the third plasma source coil has a coil bushing whose upper surface is convex.

4. The method as set forth in claim 2, wherein
the spacing between the unit coils of the first plasma source coil is uniform although the radial distance from the center of the first plasma source coil is increased,
the spacing between the unit coils of the second plasma source coil is gradually increased as the radial distance from the center of the second plasma source coil is increased, and
the spacing between the unit coils of the third plasma source coil is gradually decreased as the radial distance from the center of the third plasma source coil is increased.

5. The method as set forth in claim 2, wherein
the sectional area of each of the unit coils of the first plasma source coil is uniform although the radial distance from the center of the first plasma source coil is increased,
the sectional area of each of the unit coils of the second plasma source coil is gradually increased as the radial distance from the center of the second plasma source coil is increased, and
the sectional area of each of the unit coils of the third plasma source coil is gradually decreased as the radial distance from the center of the third plasma source coil is increased.

6. The method as set forth in claim 2, wherein the coil bushing comprises a lower bushing part and an upper bushing part, the lower bushing part being made of a material different from that of the upper bushing part.

7. The method as set forth in claim 1, wherein, if it is determined that the etching rate at the center part of the test wafer is higher than that at the edge part of the test wafer based on analysis results of the etching rate for each position of the test wafer, the first plasma source coil is replaced with the third plasma source coil, and then a main etching process is performed using the third plasma source coil.

8. The method as set forth in claim 1, wherein, if it is determined that the etching rate at the edge part of the test wafer is higher than that at the center part of the test wafer based on analysis results of the etching rate for each position of the test wafer, the first plasma source coil is replaced with the second plasma source coil, and then a main etching process is performed using the second plasma source coil.

9. A plasma etching method comprising the steps of:
mounting a wafer in a plasma chamber of a plasma chamber apparatus, the plasma chamber apparatus comprising
a plasma chamber in which a wafer is mounted,
a bias power part for applying bias power to the rear surface of the wafer,
a plasma source coil disposed on the plasma chamber for converting reaction gas introduced into the plasma chamber into plasma, the plasma source coil comprising a coil bushing and a plurality of unit coils helically wound on the coil bushing while one end of each of the unit coils is fixed to the coil bushing, and
a source power part for applying source power to the plasma source coil to generate plasma; and
supplying reaction gas into the plasma chamber while the source power is applied at a level of not more than 500 W to selectively etch the surface of the wafer.

10. The method as set forth in claim 9, wherein the number of the unit coils is three or more, and the number of turns of each of the unit coils is not more than three.

11. The method as set forth in claim 9, wherein the source power is applied at a level of approximately 300 W to 450 W.

12. The method as set forth in claim 9, wherein the ratio of the source power to the bias power is maintained within the range of between approximately 0.2:1 and 5:1.

13. The method as set forth in claim 9, wherein the reaction gas includes chlorine and boron trichloride.

14. A method of manufacturing a plasma source coil disposed on a plasma chamber, the plasma source coil comprising a coil bushing disposed in the center thereof and a plurality of unit coils helically wound on the coil bushing, wherein the method comprises the steps of:
inserting the unit coils into grooves formed at the circumferential parts of the coil bushing, respectively, and fixing the unit coils to the coil bushing;
preparing a shaping jig having depressions formed on a shaping jig body, the depressions of the shaping jig having shapes similar to those of the unit coils;
preparing a precise measuring jig having depressions formed on a precise measuring jig body, the depressions of the precise measuring jig having shapes identical to those of the unit coils;
inserting copper wires for the unit coils into the depressions of the shaping jig while applying heat to the copper wires for the unit coils to form helical copper wires having shapes similar to those of the unit coils;
inserting the helical copper wires into the depressions of the precise measuring jig while applying heat to the helical copper wires to form unit coils; and
fixing the unit coils to the coil bushing.

15. The method as set forth in claim 14, wherein the widths of the depressions formed at the shaping jig are greater than the diameters of the unit coils, respectively.

16. The method as set forth in claim 14, wherein the depressions of the shaping jig are grooves formed on the shaping jig body such that the depressions of the shaping jig have depths corresponding to the diameters of the unit coils, respectively.

17. The method as set forth in claim 14, wherein the depressions of the precise measuring jig are grooves formed on the precise measuring jig body such that the depressions of the precise measuring jig have depths corresponding to the diameters of the unit coils, respectively.

18. The method as set forth in claim 14, further comprising the step of:
after the helical copper wires are inserted into the depressions of the precise measuring jig while heat is applied to the helical copper wires to form the unit coils, pressing the precise measuring jig, in which the unit coils are inserted, for a predetermined period of time.

19. The method as set forth in claim 14, further comprising the step of:
plating the unit coils with silver.

20. The method as set forth in claim 14, wherein the unit coils are fixed to the coil bushing by means of a fixing device.

21. The method as set forth in claim 14, further comprising the step of:
rolling ends of the unit coils, which are not fixed to the coil bushing.

22. The method as set forth in claim 14, wherein the heat treatment carried out at the steps of forming the helical copper wires and the unit coils is performed at a temperature of 250 to 350° C.

23. The method as set forth in claim 14, wherein the shaping jig and the precise measuring jig are made of oxygen free copper.
